(19) United States
(12) Patent Application Publication
(10) Pub. No.: US 2025/0174522 A1
(43) Pub. Date: May 29, 2025

(54) INTEGRATED CIRCUIT DEVICE

(71) Applicant: SAMSUNG ELECTRONICS CO., LTD., SUWON-SI (KR)

(72) Inventors: Dongkyun Lim, Suwon-si (KR); Seryeun Yang, Suwon-si (KR); Jeonil Lee, Suwon-si (KR); Woohyun Jeong, Suwon-si (KR)

(21) Appl. No.: 18/767,193

(22) Filed: Jul. 9, 2024

(30) Foreign Application Priority Data
Nov. 28, 2023 (KR) 10-2023-0168236

(51) Int. Cl. H01L 23/48; H01L 29/78; H10B 12/00

(52) U.S. Cl. CPC H01L 23/481; H10B 12/315; H10B 12/50; H10D 30/63

(57) ABSTRACT

An integrated circuit device includes a semiconductor substrate having an upper surface and a lower surface opposite to the upper surface, a plurality of data output pads spaced apart from the semiconductor substrate in a vertical direction, a data output through-electrode passing through the semiconductor substrate in the vertical direction and connected to the plurality of data output pads, a plurality of bidirectional through-electrodes passing through the semiconductor substrate in the vertical direction, a power input unit electrically connected to at least one of the plurality of bidirectional through-electrodes, a cell region located disposed between the power input unit and the data output through-electrode and electrically connected to at least one of the plurality of bidirectional through-electrodes, and a peripheral circuit region comprising a plurality of peripheral gate structures electrically connected to at least one of the plurality of bidirectional through-electrodes.

### CROSS-REFERENCE TO RELATED APPLICATION

This application is based on and claims priority under 35 U.S.C. § 119 to Korean Patent Application No. 10-2023-0168236, filed on Nov. 28, 2023, in the Korean Intellectual Property Office, the disclosure of which is incorporated by reference herein in its entirety.

### BACKGROUND

### 1. Technical Field

The inventive concept relates to an integrated circuit device.

### 2. Discussion of Related Art

As the integration of circuit devices increases, a speed of operation and an accuracy of operation in the circuit devices may be difficult to maintain. For example, in some integrated circuit devices, power signals and data signals may be input simultaneously to a through-electrode, however noise from the power signals may be introduced into the data signals.

### SUMMARY

The inventive concept provides an integrated circuit device having improved reliability.

The inventive concept also provides a semiconductor package formed by packaging a plurality of integrated circuit devices having improved reliability.

According to an aspect of the inventive concept, an integrated circuit device includes a semiconductor substrate having an upper surface and a lower surface opposite to the upper surface, a plurality of data output pads spaced apart from the semiconductor substrate in a vertical direction, a data output through-electrode passing through the semiconductor substrate in the vertical direction and connected to the plurality of data output pads, a plurality of bidirectional through-electrodes including a plurality of first small through-electrodes each passing through a first portion of the semiconductor substrate from the upper surface of the semiconductor substrate in the vertical direction and a plurality of second small through-electrodes each passing through a second portion of the semiconductor substrate from the lower surface of the semiconductor substrate in the vertical direction, a power input unit electrically connected to at least one of the plurality of first small through-electrodes, a cell region disposed between the power input unit and the data output through-electrode and electrically connected to at least one of the plurality of first small through-electrodes, and a peripheral circuit region including a plurality of peripheral gate structures electrically connected to at least one of the plurality of second small through-electrodes.

According to another aspect of the inventive concept, an integrated circuit device includes a semiconductor substrate having an upper surface and a lower surface opposite to the upper surface, the semiconductor substrate extending in a first direction and a second direction perpendicular to the first direction, a cell region disposed above the upper surface of the semiconductor substrate and including a vertical channel transistor and a plurality of capacitors electrically connected to the vertical channel transistor, a power input unit disposed on a side of the cell region and electrically connected to the cell region, a plurality of data output pads spaced apart from the semiconductor substrate in a vertical direction, a data output through-electrode disposed on a second side of the cell region opposite the power input unit in a horizontal direction, the data output through-electrode passing through the semiconductor substrate in the vertical direction and connected to the plurality of data output pads, and providing a path to output data from the cell region, a peripheral circuit region disposed on the lower surface of the semiconductor substrate, the peripheral circuit region electrically connected to the power input unit and the data output through-electrode and including a plurality of peripheral gate structures, and a plurality of bidirectional through-electrodes including a plurality of first small through-electrodes each electrically connected to the cell region and passing through a first portion of the semiconductor substrate from the upper surface of the semiconductor substrate in the vertical direction and a plurality of second small through-electrodes each electrically connected to the peripheral circuit region and passing through a second portion of the semiconductor substrate from the lower surface of the semiconductor substrate in the vertical direction, wherein, when power is defined as a product of a magnitude of voltage and a magnitude of current, the data output through-electrode is configured to receive first power, the power input unit is configured to receive second power, and the first power is less than the second power, wherein the peripheral circuit region further includes a floating pad electrically connecting the plurality of peripheral gate structures to the data output through-electrode, wherein the floating pad is spaced apart from a data output pad of the plurality of data output pads disposed below the lower surface of the semiconductor substrate.

According to another aspect of the inventive concept, a semiconductor package includes a plurality of integrated circuit devices stacked in a vertical direction and a plurality of connection terminals disposed between the integrated circuit devices and configured to electrically connect the plurality of integrated circuit devices to each other, wherein each of the integrated circuit devices includes a semiconductor substrate having an upper surface and a lower surface opposite to the upper surface, the semiconductor substrate extending in a first direction and a second direction perpendicular to the first direction, a cell region disposed above the upper surface of the semiconductor substrate and comprising a vertical channel transistor and a plurality of capacitors electrically connected to the vertical channel transistor, a plurality of bidirectional through-electrodes including a plurality of first small through-electrodes each passing through a first portion of the semiconductor substrate from the upper surface of the semiconductor substrate in the vertical direction and a plurality of second small through-electrodes each passing through a second portion of the semiconductor substrate from the lower surface of the semiconductor substrate in the vertical direction, a data output through-electrode passing through the semiconductor substrate in the vertical direction and electrically connected to a floating pad located in a peripheral circuit region and configured to output data, a power input unit connected to at least one of the plurality of bidirectional through-electrodes and configured to input power, and a cell connector disposed on a side of the power input unit and configured to electrically connect the power input unit and the cell region to each other, wherein the plurality of first small through-electrodes and the plurality of second small through-electrodes are electrically and respectively connected to each other, wherein, when power is defined as a product of a magnitude of voltage and a magnitude of current, the data output through-electrode is configured to receive first power, the power input unit is configured to receive second power, and the first power is less than the second power, wherein the floating pad is in direct physical contact with the data output through-electrode, the cell region is disposed above the upper surface of the semiconductor substrate, and the peripheral circuit region is disposed on the lower surface of the semiconductor substrate, wherein the plurality of connection terminals include a cell connection terminal configured to electrically connect the plurality of cell regions and the peripheral circuit region to each other and a data connection terminal configured to electrically connect the plurality of data output through-electrodes to each other.

### BRIEF DESCRIPTION OF THE DRAWINGS

Embodiments will be more clearly understood from the following detailed description taken in conjunction with the accompanying drawings in which:

FIG. 1 is a plan view of an integrated circuit device according to an embodiment;

FIG. 2A is an enlarged view of a cross-section of the integrated circuit device, taken along line X-X′ of FIG. 1;

FIG. 2B is an enlarged three-dimensional perspective view of region A of FIG. 2A;

FIG. 2C is an enlarged cross-sectional view of region B1 of FIG. 2A;

FIG. 2D is an enlarged three-dimensional perspective view of region B1 of FIG. 2A;

FIG. 2E is an enlarged cross-sectional view of region B2 of FIG. 2A, according to an embodiment;

FIG. 2F, FIG. 2G, and FIG. 2H are enlarged cross-sectional views of region B2 of FIG. 2A, according to some embodiments;

FIG. 3 is a cross-sectional view of a semiconductor package according to an embodiment;

FIG. 4A, FIG. 4B, FIG. 4C, and FIG. 4D are cross-sectional views of integrated circuit devices according to some embodiments;

FIG. 4E is an enlarged three-dimensional perspective view of region B3 of FIG. 4B;

FIG. 5A and FIG. 5B are cross-sectional views of integrated circuit devices according to some embodiments;

FIG. 5C is an enlarged three-dimensional perspective view of region C of FIG. 5B;

FIG. 5D and FIG. 5E are cross-sectional views of integrated circuit devices according to some embodiments; and

FIGS. 6 to 11 are cross-sectional views illustrating a method of manufacturing an integrated circuit device, according to an embodiment.

### DETAILED DESCRIPTION

Hereinafter, embodiments of the inventive concept will be described in detail with reference to the attached drawings. The same reference numerals are used for the same components in the drawings, and redundant descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

Examples or illustrative terms may be used to explain the technical idea in detail, and thus, the scope of the inventive concept is not limited by these examples or illustrative terms unless limited by the claims.

Unless otherwise specified, in this specification, a vertical direction may be defined as a Z direction, and a first direction and a second direction may each be defined as a direction perpendicular to the Z direction. The first direction may be referred to as an X direction and the second direction may be referred to as a Y direction, which intersects the first direction. A vertical level may refer to a height level in the vertical direction (Z). A horizontal width may refer to a length in the horizontal direction (X and/or Y) and a vertical length may refer to a length in the vertical direction (Z direction).

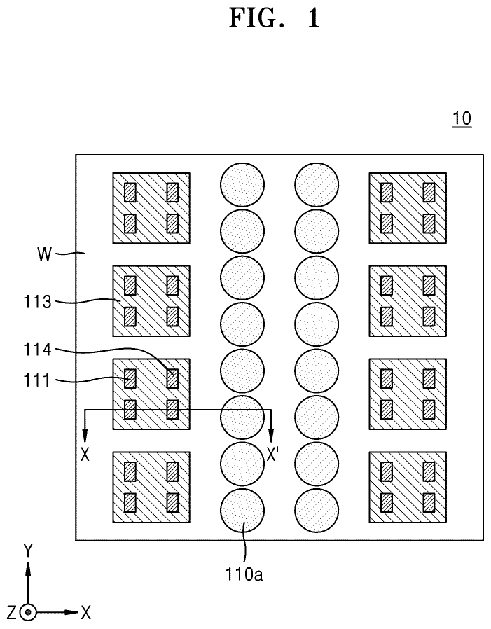

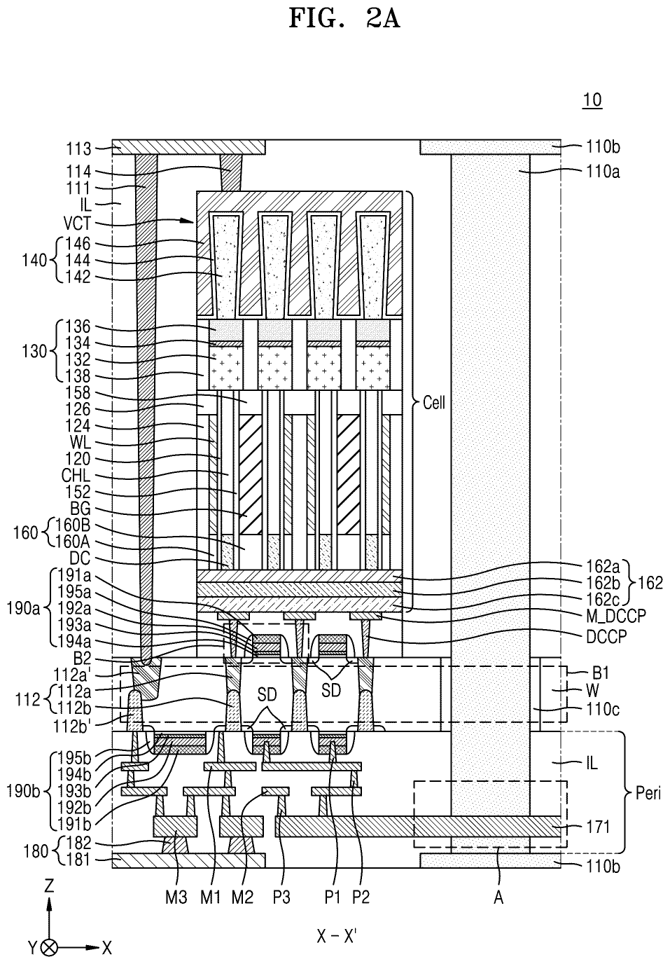

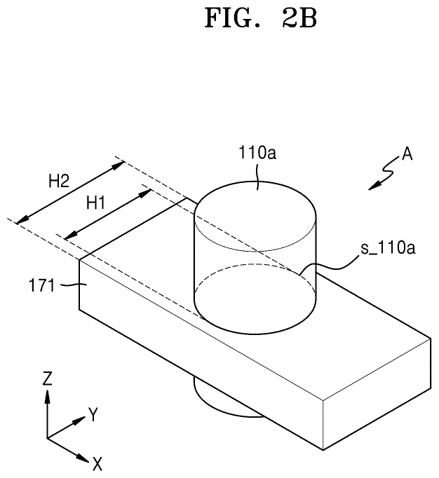

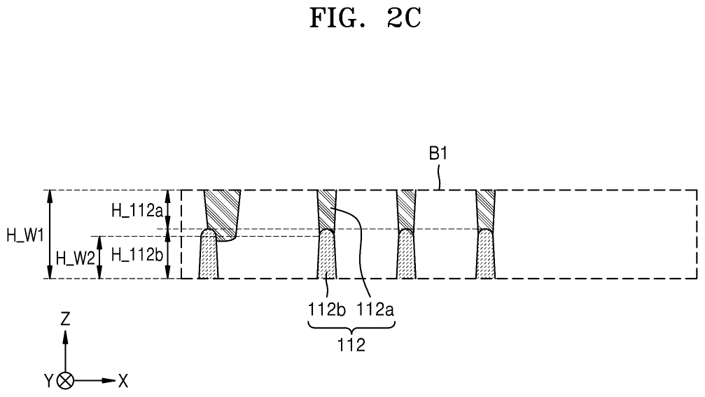

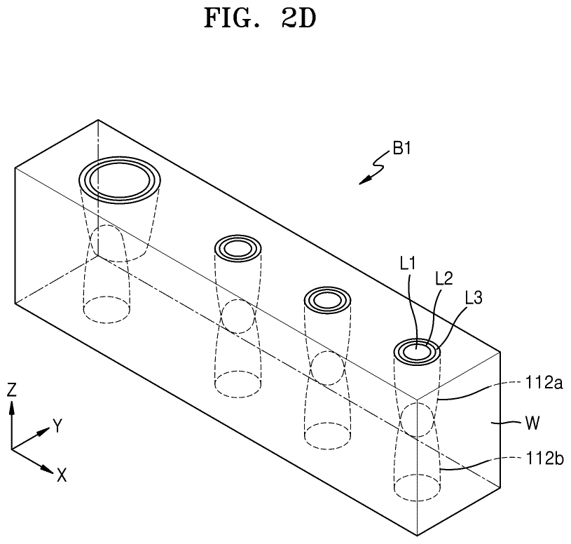

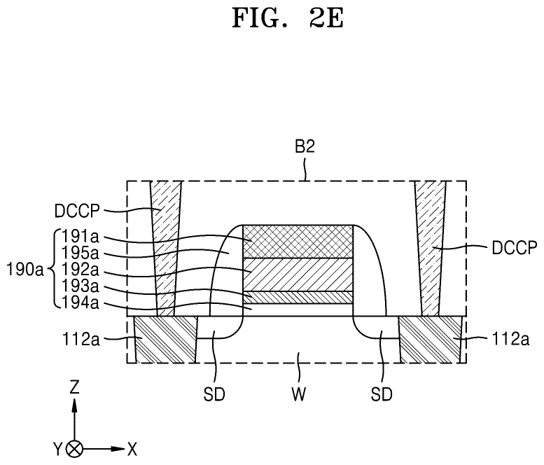

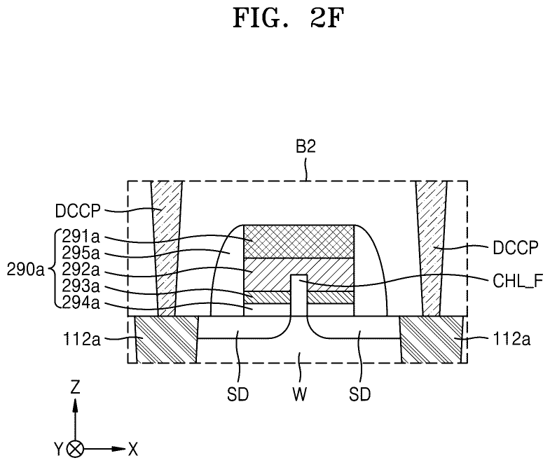

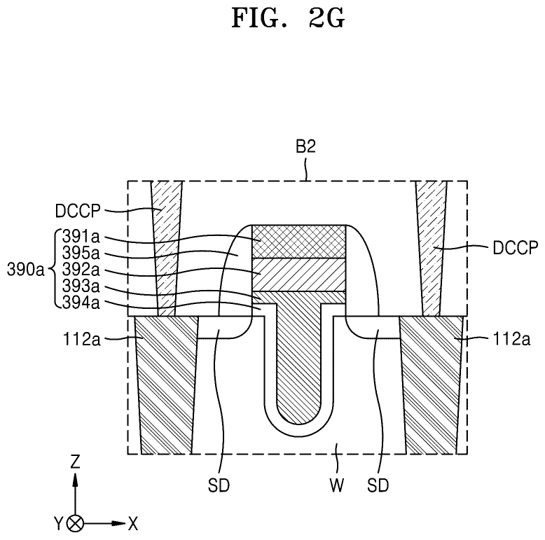

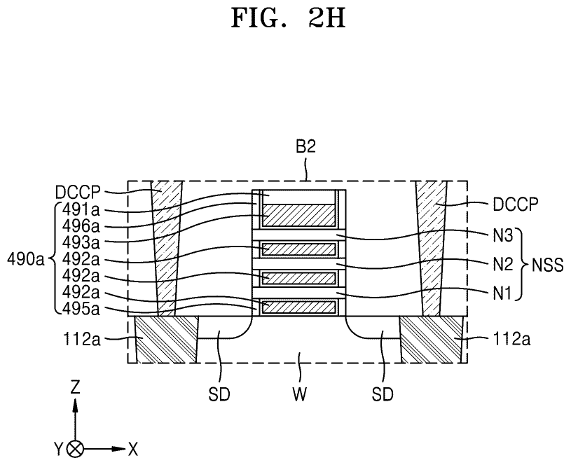

FIG. 1 is a plan view of an integrated circuit device 10 according to an embodiment. FIG. 2A is a cross-sectional view of the integrated circuit device 10, taken along line X-X′ of FIG. 1.

Referring to FIG. 1 and FIG. 2A, the integrated circuit device 10 may include a semiconductor substrate W having an upper surface and a lower surface opposite to the upper surface. The semiconductor substrate W may extend in a first direction X and a second direction Y perpendicular to the first direction X.

In some embodiments, the semiconductor substrate W may include a semiconductor wafer. In some embodiments, the semiconductor substrate W may include silicon (Si). In some embodiments, the semiconductor substrate W may include semiconductor elements, such as germanium (Ge), or compound semiconductors, such as silicon carbide (SiC), gallium arsenide (GaAs), indium arsenide (InAs), or indium phosphide (InP). In at least one embodiment, the semiconductor substrate W may have a silicon on insulator (SOI) structure. For example, the semiconductor substrate W may have a buried oxide (BOX) layer. In some embodiments, the semiconductor substrate W may include a conductive region, for example, a well doped with impurities or a structure doped with impurities. The semiconductor substrate W may have various device isolation structures, such as a shallow trench isolation (STI) structure.

A plurality of various types of individual devices may be formed on the semiconductor substrate W. The plurality of individual devices may include various electronic devices (microelectronic devices), for example, metal-oxide-semiconductor field effect transistors (MOSFET), system large scale integration (LSI), image sensors, such as complementary metal-oxide-semiconductor (CMOS) imaging sensors (CIS), micro-electro-mechanical systems (MEMS), active elements, passive elements, etc.

The integrated circuit device 10 may include a plurality of data output pads 110b. Each of the data output pads of the plurality of data output pads 110b may be spaced apart from the semiconductor substrate W in the vertical direction. The integrated circuit device 10 may include at least one data output through-electrode 110a passing through the semiconductor substrate W and connected to at least two data output pads 110b among the plurality of data output pads 110b. For example, the data output through-electrode 110a may connect a first data output pad of the plurality of data output pads 110b disposed above the upper surface of the semiconductor substrate W to a second data output pad of the plurality of data output pads 110b disposed below the lower surface of the semiconductor substrate W. The data output through-electrode 110a passing through the semiconductor substrate W in the vertical direction may provide a path configured to output data.

The data output through-electrode 110a may correspond to a through silicon via (TSV). For reference, the data output through-electrode 110a may be a via-first structure, a via-middle structure, or a via-last structure. The via-first structure may be formed before formation of an integrated circuit layer, the via-middle structure may be formed after formation of an integrated circuit layer and before formation of a wiring layer, and the via-last structure may be formed after formation of a wiring layer. In FIG. 2A, the data output through-electrode 110a may be classified as the via-last structure.

In a plan view, data output through-electrodes 110a may be disposed in rows. For example, the data output through-electrodes 110a may be disposed in two rows on a central portion of the semiconductor substrate W. The data output through-electrodes 110a may be disposed in symmetric rows. The number or shape of the plurality of data output through-electrodes 110a is not limited to that shown in the drawings.

The data output pads 110b may be respectively located at the upper end portion and lower end portion of the data output through-electrode 110a. A horizontal width of the data output through-electrode 110a may be less than a horizontal width of the data output pad 110b. Each of the data output through-electrodes 110a and the data output pads 110b may include, for example, copper (Cu), carbon nanotubes, or an alloy containing copper (Cu). The data output through-electrode 110a may be in physical contact with, and electrically connected to a floating pad 171 located in a peripheral circuit region Peri, as described herein. Power and data signals may be input to through-electrodes. The data signals may be transmitted via the data output through-electrodes 110a according to the inventive concept.

The data output through-electrode 110a may pass through the semiconductor substrate W in the vertical direction, and an insulating spacer 110c may be disposed between the semiconductor substrate W and the data output through-electrode 110a. The insulating spacer 110c may prevent the data output through-electrode 110a from being short-circuited with the semiconductor substrate W when a current or voltage for data signals flows via the data output through-electrode 110a. The insulating spacer 110c may surround an outer wall of the data output through-electrode 110a with respect to a portion of the vertical length of the data output through-electrode 110a. For example, a height of the insulating spacer 110c may be the same as a height of the semiconductor substrate W. The semiconductor substrate W and the insulating spacer 110c may be disposed on the peripheral circuit region Peri.

The integrated circuit device 10 may include a plurality of bidirectional through-electrodes 112. Each bidirectional through-electrode 112 may include a first small through-electrodes 112a and a second small through-electrodes 112b. The plurality of first small through-electrodes 112a may each pass through a first portion of the semiconductor substrate W from the upper surface of the semiconductor substrate W in the vertical direction Z. The plurality of second small through-electrodes 112b may each pass through a second portion of the semiconductor substrate W from the lower surface of the semiconductor substrate W in the vertical direction Z.

The plurality of first small through-electrodes 112a and the plurality of second small through-electrodes 112b may include different materials. The lengths of the plurality of first small through-electrodes 112a in the vertical direction Z may be different from the lengths of the plurality of second small through-electrodes 112b in the vertical direction Z. The plurality of second small through-electrodes 112b may be formed after the plurality of first small through-electrodes 112a are formed. For example, the plurality of second small through-electrodes 112b may be disposed on the plurality of first small through-electrodes 112a and the semiconductor substrate W may be flip-chip mounted on the peripheral circuit region Peri. An end portion of the first small through-electrode 112a may have a concave shape. For example, the end portion of the first small through-electrode 112a disposed on the second small through-electrode 112b may have a concave shape. An end portion of the second small through-electrode 112b may have a convex shape. For example, the end portion of the second small through-electrode 112b disposed on the first small through-electrode 112a may have a convex shape. The plurality of first small through-electrodes 112a and the plurality of second small through-electrodes 112b may be electrically and respectively connected to each other. For example, the end portion of the second small through-electrode 112b may be a projection filling the end portion of the first small through-electrode 112a.

At least one of the plurality of first small through-electrodes 112a may be electrically connected to a cell region Cell. The cell region Cell may be disposed on the upper surface of the semiconductor substrate W, as described herein. A direct contact plug DCCP may be disposed between the cell region Cell and the semiconductor substrate W. At least one of the first small through-electrodes 112a may be electrically connected to a direct contact plug DCCP connected to the cell region Cell.

A plurality of core gate structures 190a may be disposed on the semiconductor substrate W. Source/drain regions SD may be disposed on sides of the core gate structure 190a. The source/drain regions SD may be disposed in the semiconductor substrate W. The first small through-electrodes 112a may be electrically connected to portions of the source/drain regions SD. At least one of the plurality of second small through-electrodes 112b may be electrically connected to the peripheral circuit region Peri disposed on the lower surface of the semiconductor substrate W, as described herein.

The first small through-electrode 112a and the second small through-electrode 112b may each have a tapered shape. A tapered shape of the first small through-electrode 112a and the second small through-electrode 112b may each have a horizontal width that is reduced toward a center of the semiconductor substrate W in the vertical direction. For example, relatively thin portions of the first small through-electrode 112a and the second small through-electrode 112b may meet each other near the center of the semiconductor substrate W in the vertical direction. The horizontal widths of the plurality of first small through-electrodes 112a and the plurality of second small through-electrodes 112b may be less than the horizontal width of the data output through-electrode 110a. More particularly, the horizontal width of the plurality of first small through-electrodes 112a and the horizontal width of the second small through-electrodes 112b away from the center portion of the semiconductor substrate W is less than a horizontal width of the data output through-electrode 110a. For example, a maximum value of the horizontal widths of the plurality of first small through-electrodes 112a and the plurality of second small through-electrodes 112b may be less than the horizontal width of the data output through-electrode 110a.

Each of the source/drain regions SD may include at least a portion of the semiconductor substrate W doped with impurities. Although not shown, a portion of the semiconductor substrate W below the core gate structure 190a may correspond to a channel region. The source/drain regions SD may be located at both sides of the channel region.

The core gate structure 190a may be disposed on the upper surface of the semiconductor substrate W. The core gate structure 190a may include a gate dielectric layer 194a, a first conductive layer 193a, a second conductive layer 192a, and a capping layer 191a, sequentially disposed. The core gate structure 190a may include, for example, a planar field effect transistor, a fin field effect transistor, a recessed channel array transistor, or a multi bridge channel field effect transistor. Examples are described herein in detail with reference to FIGS. 2E to 2H.

The gate dielectric layer 194a may include silicon oxide, silicon nitride, or a high-k dielectric material, or a combination thereof. The high-k dielectric material may have a higher dielectric constant than silicon oxide and include, for example hafnium oxide (HfO₂), zirconium oxide (ZrO₂), aluminum oxide (Al₂O₃), hafnium aluminum oxide (HfAlO₃), tantalum oxide (Ta₂O₃), or titanium oxide (TiO₂), or a combination thereof.

The first conductive layer 193a and the second conductive layer 192a may each include a conductive material. For example, the first conductive layer 193a may include polysilicon and the second conductive layer 192a may include titanium silicon nitride (TiSiN). The capping layer 191a may include silicon nitride. A first spacer 195a may be located on a side surface of the core gate structure 190a. The first spacer 195a may include silicon oxide. In some embodiments, the thickness of the first spacer 195a in the first direction X may decrease in the vertical direction Z. For example, the first spacer 195a may be relatively thin adjacent to the capping layer 191a and relatively thick adjacent to the gate dielectric layer 194a.

A peripheral gate structure 190b may be disposed on the lower surface of the semiconductor substrate W. The peripheral gate structure 190b may include a peripheral gate dielectric layer 194b, a peripheral first conductive layer 193b, a peripheral second conductive layer 192b, and a peripheral capping layer 191b, sequentially disposed.

The peripheral gate dielectric layer 194b may include silicon oxide, silicon nitride, or a high-k dielectric material, or a combination thereof. The high-k dielectric material may have a higher dielectric constant than silicon oxide and include, for example hafnium oxide (HfO₂), zirconium oxide (ZrO₂), aluminum oxide (Al₂O₃), hafnium aluminum oxide (HfAlO₃), tantalum oxide (Ta₂O₃), or titanium oxide (TiO₂), or a combination thereof.

The peripheral first conductive layer 193b and the peripheral second conductive layer 192b may each include a conductive material. For example, the peripheral first conductive layer 193b may include polysilicon and the peripheral second conductive layer 192b may include titanium silicon nitride (TiSiN). The peripheral capping layer 191b may include silicon nitride. A peripheral first spacer 195b may be located on a side surface of the peripheral gate structure 190b. The peripheral first spacer 195b may include silicon oxide. In some embodiments, the thickness of the peripheral first spacer 195b in the first direction X may decrease in the vertical direction Z. For example, the peripheral first spacer 195b may be relatively thin adjacent to the peripheral capping layer 191b and relatively thick adjacent to the peripheral gate dielectric layer 194b.

The integrated circuit device 10 may include a power input unit 111. The power input unit 111 may be electrically connected to at least one of the plurality of first small through-electrodes 112a. The power input unit 111 may be electrically connected to a peripheral small through-electrodes 112a′ of the plurality of first small through-electrodes 112a. The shape of a peripheral small through-electrode 112a′ may be different from the shape of at least one of the plurality of first small through-electrodes 112a electrically connected to the cell region Cell, as described herein. A groove may be disposed in an upper surface of the peripheral small through-electrode 112a′. The power input unit 111 may be connected to the peripheral small through-electrode 112a′ at the groove in the peripheral small through-electrode 112a′. The power input unit 111 may include the same material as the peripheral small through-electrode 112a′. Voltage or current may flow via the power input unit 111, and power may be input to the power input unit 111. When the power is defined as the product of the magnitude of voltage and the magnitude of current, the data output through-electrode 110a may be configured to receive first power and the power input unit 111 may be configured to receive second power. The first power may be less than the second power.

The integrated circuit device 10 may include the cell region Cell. The cell region Cell may be disposed between the power input unit 111 and the data output through-electrode 110a in the first direction X. The cell region Cell may be electrically connected to at least one of the plurality of first small through-electrodes 112a.

The integrated circuit device 10 may further include an upper wiring pad 113. The upper wiring pad 113 may be disposed on the power input unit 111. The upper wiring pad 113 may be electrically connected to the power input unit 111 and a cell connector 114 located between the upper wiring pad 113 and the cell region Cell in the second direction Y.

In a plan view as shown in FIG. 1, a plurality of upper wiring pads 113 may be arranged in rows at end portions of the semiconductor substrate W. A plurality of power input units 111 and a plurality of cell connectors 114 may be arranged on the upper wiring pad 113. The numbers and shapes thereof are not limited to that illustrated in the drawings. The cell connector 114 may be configured to electrically connect the upper wiring pad 113 to a plurality of capacitors 140, as described herein.

The cell region Cell may include a vertical channel transistor VCT and the plurality of capacitors 140 electrically connected to the vertical channel transistor VCT.

The vertical channel transistor VCT may include a conductive line 162, a plurality of channel regions CHL, a back gate electrode BG, and a pair of word lines WL. The conductive line 162 may extend in the first direction X, and the plurality of channel regions CHL may be arranged on the conductive line 162, spaced apart from each other in the first direction X, and electrically connected to the conductive line 162. The back gate electrode BG selected from among the plurality of channel regions CHL, may extend lengthwise in the second direction Y between a first channel region and a second channel region adjacent to each other, and spaced apart from the conductive line 162 in the vertical direction. The pair of word lines WL selected from among the plurality of channel regions CHL may be disposed between the second channel region and a third channel region adjacent to each other, and may be spaced apart from each other in the first direction X. Also, the conductive line 162 may include a plurality of layers. Each of the plurality of conductive lines 162 may form a bit line.

The plurality of channel regions CHL may be disposed on each of the plurality of conductive lines 162, and a plurality of contact plugs 130 may be respectively disposed on the plurality of channel regions CHL. Between the plurality of conductive lines 162 and the plurality of contact plugs 130, the plurality of channel regions CHL may be spaced apart from each other and repeatedly arranged in the first direction X and the second direction Y. Each of the plurality of channel regions CHL may have a first end portion spaced apart from the plurality of conductive lines 162 in the vertical direction Z and a second end portion connected to a contact plug 130 selected from among the plurality of contact plugs 130. Each of the plurality of channel regions CHL may be physically spaced apart from the conductive line 162 and in contact with a contact plug 130.

Each of the plurality of conductive lines 162 may include polysilicon doped with metal or conductive metal nitride. For example, the plurality of conductive lines 162 may each include Ti, TiN, Ta, TaN, Mo, Ru, W, WN, Co, Ni, or RuTiN, or a combination thereof. The plurality of conductive lines 162 may include a first layer 162a, a second layer 162b, and a third layer 162c, sequentially stacked. The first layer 162a may include polysilicon. The second layer 162b below the first layer 162a may include polysilicon doped with conductive metal nitride. The third layer 162c below the second layer 162b may include metal.

The plurality of contact plugs 130 may be spaced apart from the plurality of conductive lines 162 in the vertical direction Z with the plurality of channel regions CHL disposed therebetween. The plurality of contact plugs 130 may be arranged in a matrix form so as to be spaced apart from each other in the first horizontal direction X and the second horizontal direction Y. The plurality of contact plugs 130 may be connected to the plurality of channel regions CHL in a one to one relationship.

Each of the plurality of contact plugs 130 may include metal, conductive metal nitride, metal silicide, or doped polysilicon, or a combination thereof. For example, the plurality of contact plugs 130 may each include Ti, TiN, Ta, TaN, Mo, Ru, W, WN, Co, Ni, TiSi, TiSiN, WSi, WSiN, TaSi, TaSiN, RuTiN, CoSi, NiSi, or doped polysilicon, or a combination thereof. In some embodiments, the plurality of contact plugs 130 may each include a first conductive pattern 132, a second conductive pattern 134, and a third conductive pattern 136, which may be sequentially stacked on the plurality of channel regions CHL as illustrated in FIG. 2A. For example, the first conductive pattern 132 may include doped polysilicon, the second conductive pattern 134 may include metal silicide, and the third conductive pattern 136 may include metal. However, the disclosure is not limited thereto.

The plurality of channel regions CHL may include a first group of channel regions CHL arranged in a row in the first direction X and spaced apart from each other in the first direction X and a second group of channel regions CHL arranged in a row in the second direction Y and spaced apart from each other in the second direction Y. Each of the plurality of contact plugs 130 may be disposed on one channel region CHL selected from among the plurality of channel regions CHL. Each of the plurality of contact plugs 130 may pass through an interlayer insulating film 138 and come into contact with the selected one channel region CHL. The interlayer insulating film 138 may include a silicon oxide film, or a silicon nitride film, or a combination thereof.

In some embodiments, each of the plurality of channel regions CHL may include silicon, for example, single crystalline silicon, polycrystalline silicon, or amorphous silicon. In some embodiments, each of the plurality of channel regions CHL may include at least one selected from a group consisting of Ge, SiGe, SiC, GaAs, InAs, and InP. In some embodiments, the channel region CHL may include a conductive region, for example, a well doped with impurities or a structure doped with impurities.

A plurality of back gate electrodes BG and a plurality of word lines WL may be disposed on each of the plurality of conductive lines 162. The plurality of back gate electrodes BG and the plurality of word lines WL may each extend lengthwise in the second horizontal direction Y between the plurality of conductive lines 162 and the plurality of contact plugs 130. The plurality of back gate electrodes BG and the plurality of word lines WL may be spaced apart from each other in the first direction X.

An isolation insulating pattern 124 may be located between a pair of word lines WL that are arranged between a pair of channel regions CHL disposed adjacent to each other. A first buried insulating pattern 126 may be located between the pair of word lines WL and the plurality of contact plugs 130. For example, the first buried insulating pattern 126 may disposed on the pair of word lines WL, and may contact the plurality of contact plugs 130. A pair of second buried insulating patterns 160A may be disposed between the pair of word lines WL and the plurality of conductive lines 162. The word line WL, the first buried insulating pattern 126, and the second buried insulating pattern 160A may overlap each other in the vertical direction (Z direction) between the pair of channel regions CHL disposed adjacent to each other. The pair of word lines WL may be spaced apart from the plurality of contact plugs 130 in the vertical direction (Z direction) with the first buried insulating pattern 126 disposed therebetween. The word line WL may be spaced apart from the conductive line 162 with the second buried insulating pattern 160A disposed therebetween. In the vertical direction (Z direction), the length of the second buried insulating pattern 160A may be equal or similar to the length of a second capping insulating pattern 160B. The second buried insulating pattern 160A and the second capping insulating pattern 160B may form a buried structure 160 in contact with the conductive line 162.

For the plurality of back gate electrodes BG and the plurality of word lines WL aligned in a row in the first direction X on a conductive line 162, a back gate electrode BG and a pair of word lines WL may be arranged alternately, and the back gate electrode BG and the pair of word lines WL may be spaced apart from each other with a channel region CHL disposed therebetween. For example, the plurality of word lines WL may be arranged such that a pair of word lines WL adjacent to each other are disposed in each space between the plurality of back gate electrodes BG.

Each of the plurality of back gate electrodes BG may include metal, conductive metal nitride, or doped polysilicon, or a combination thereof. For example, each of the plurality of back gate electrodes BG may include Ti, TiN, Ta, TaN, Mo, Ru, W, WN, TiSiN, WSiN, or doped polysilicon, or a combination thereof, but the disclosure is not limited thereto. Each of the plurality of word lines WL may include metal or conductive metal nitride, or a combination thereof. For example, each of the plurality of word lines WL may include Ti, TiN, Ta, TaN, Mo, Ru, W, WN, TiSiN, or WSiN, or a combination thereof, but the disclosure is not limited thereto.

Each of the plurality of back gate electrodes BG may extend lengthwise in the second direction Y and be disposed between two channel regions CHL disposed adjacent to each other in the first direction X. Each of the plurality of back gate electrodes BG may be spaced apart from the conductive line 162 and each of the plurality of contact plugs 130 in the vertical direction Z.

The integrated circuit device 10 may include a plurality of back gate dielectric films 152 disposed on the plurality of back gate electrodes BG. Each of the plurality of back gate dielectric films 152 may be located between a back gate electrode BG and a channel region CHL. Each of the plurality of back gate dielectric films 152 may be in contact with an adjacent back gate electrode BG and an adjacent channel region CHL. Each of the plurality of back gate dielectric films 152 may include a first end portion in contact with the conductive line 162 and a second end portion in contact with the contact plug 130.

Between a pair of channel regions CHL disposed adjacent to each other, a first capping insulating pattern 158 may be located between the back gate electrode BG and the plurality of contact plugs 130. Between a pair of channel regions CHL adjacent to each other, the second capping insulating pattern 160B may be located between the back gate electrode BG and the conductive line 162. The first capping insulating pattern 158, the back gate electrode BG, and the second capping insulating pattern 160B may overlap each other in the vertical direction Z.

Each of the first capping insulating pattern 158 and the second capping insulating pattern 160B may include a silicon oxide film or a silicon nitride film, or a combination thereof. In some embodiments, the first capping insulating pattern 158 and the second capping insulating pattern 160B may include different materials. For example, the first capping insulating pattern 158 may include a silicon oxide film and the second capping insulating pattern 160B may include a silicon nitride film. In some embodiments, the first capping insulating pattern 158 and the second capping insulating pattern 160B may include the same material. For example, the first capping insulating pattern 158 and the second capping insulating pattern 160B may include the same material, for example, a silicon oxide film or a silicon nitride film.

Each of the plurality of word lines WL may be spaced apart from the conductive line 162 and each of the plurality of contact plugs 130 in the vertical direction Z. A pair of word lines WL may be disposed in each space between the plurality of back gate electrodes BG in the first direction X. The pair of word lines WL may be spaced apart from an adjacent back gate electrode BG in the first direction X with a channel region CHL disposed therebetween.

The integrated circuit device 10 may include the peripheral circuit region Peri that includes a plurality of peripheral gate structures 190b electrically connected to at least one of the plurality of second small through-electrodes 112b. The peripheral circuit region Peri may include a planar field effect transistor, a fin field effect transistor, or a multi bridge channel field effect transistor.

The peripheral circuit region Peri may include a plurality of wiring layers M1, M2, and M3, a plurality of conductive plugs P1, P2, and P3, and an insulating layer IL surrounding the plurality of wiring layers M1, M2, and M3 and the plurality of conductive plugs P1, P2, and P3. The plurality of wiring layers M1, M2, and M3 may be electrically connected to the plurality of second small through-electrodes 112b. The plurality of conductive plugs P1, P2, and P3 may each be in contact with and connected to some of the plurality of wiring layers M1, M2, and M3. Some of the plurality of conductive plugs P1, P2, and P3 may be disposed in contact with the peripheral gate structure 190b. Each of the plurality of conductive plugs P1, P2, and P3 may have a tapered shape. The tapered shape of the plurality of conductive plugs P1, P2, and P3 may have a horizontal width that may be reduced toward the lower surface of the semiconductor substrate W.

The peripheral circuit region Peri may include a lower wire 180 disposed in a lower portion of the peripheral circuit region Peri. The lower wire 180 may include a lower wiring pad 181 and a plurality of lower wiring plugs 182. The lower wiring plugs 182 may be in contact with at least some of the plurality of wiring layers M1, M2, and M3. The lower wiring pad 181 may be disposed in contact with the lower wiring plugs 182.

Some of the plurality of conductive plugs P1, P2, and P3 may be in contact with the peripheral gate structure 190b.

The peripheral circuit region Peri may include the floating pad 171. The floating pad 171 may electrically connect the plurality of peripheral gate structures 190b to the data output through-electrode 110a. The floating pad 171 may not contact the data output pad 110b. For example, the floating pad 171 may be spaced apart from the data output pad 110b in the vertical direction. Some of the plurality of conductive plugs P1, P2, and P3 may be in contact with the floating pad 171. Components of the peripheral circuit region Peri may include metal as conductive materials. FIG. 2B is an enlarged three-dimensional perspective view of region A of FIG. 2A.

Referring to FIG. 2B together with FIG. 2A, the floating pad 171 may have a shape in which a through-hole s_110a for accommodating the data output through-electrode 110a is formed such that the data output through-electrode 110a passes through the floating pad 171 in the vertical direction Z. When the floating pad 171 has a shape with the through-hole s_110a disposed therein, a width H1 of the data output through-electrode 110a in the second direction Y may be less than a width H2 of the floating pad 171 in the second direction Y.

FIG. 2C is an enlarged cross-sectional view of region B1 of FIG. 2A.

Referring to FIG. 2C together with FIG. 2A, at least one of a vertical length H_112a of the plurality of first small through-electrodes 112a and a vertical length H_112b of the second small through-electrodes 112b in the vertical direction Z may be less than a vertical length H_W2. The vertical length H_W2 may be half of a vertical length H_W1 of the semiconductor substrate W. FIG. 2C illustrates a configuration in which the vertical length H_112a of the first small through-electrodes 112a is less than the vertical length H_W2 that is half of the vertical length H_W1 of the semiconductor substrate W.

FIG. 2D is an enlarged three-dimensional perspective view of region B1 of FIG. 2A.

Each of the first small through-electrode 112a and the second small through-electrode 112b may have the tapered shape of which the horizontal width is reduced toward the center portion of the semiconductor substrate W in the vertical direction. A plurality of first tapered holes may be formed for forming the plurality of first small through-electrodes 112a, and a plurality second tapered holes may be formed for forming the plurality of second small through-electrodes 112b. The first small through-electrodes 112a may be formed before the plurality of second small through-electrodes 112b. For example, the first small through-electrodes 112a may be formed, and the plurality second tapered holes may be formed for forming the plurality of second small through-electrodes 112b, which may simultaneously form the groove in an end portion of each of the first small through-electrodes 112a. However, the disclosure is not limited thereto.

A plurality of layers may be deposited in each of the plurality first tapered holes and the plurality second tapered holes for the first small through-electrodes 112a and the second small through-electrodes 112b.

The plurality of layers may include at least three layers, and FIG. 2D illustrates three layers for convenience of description. However, the disclosure is not limited thereto.

A first layer L1 may be formed about the central portion of each of the first small through-electrodes 112a and the second small through-electrodes 112b. The first layer L1 may include a metal layer. The first layer L1 may include tungsten (W), but the disclosure is not limited thereto.

A second layer L2 may be formed surrounding the outer circumferential surface of the first layer L1. The second layer L2 may include a barrier metal layer. The second layer L2 may include Ti, TiN, Ta, TaN, Mo, Ru, W, WN, Co, Ni, or RuTiN, or a combination thereof.

A third layer L3 may be formed surrounding the outer circumferential surface of the second layer L2. The third layer L3 may include a non-conductive layer. The third layer L3 may include silicon, for example, single crystalline silicon, polycrystalline silicon, or amorphous silicon.

In some embodiments, the third layer L3 may be formed on a side wall of the tapered opening, the second layer L2 may be formed on the third layer L3, and the first layer L1 may be formed on the second L1.

FIG. 2E is an enlarged cross-sectional view of region B2 of FIG. 2A, according to an embodiment. FIG. 2F, FIG. 2G, and FIG. 2H are enlarged cross-sectional views of region B2 of FIG. 2A, according to some embodiments.

In the case of FIG. 2E, the core gate structure 190a may include a planar field effect transistor. The planar field effect transistor may include a gate dielectric layer 194a, a first conductive layer 193a, a second conductive layer 192a, and a capping layer 191a. The gate dielectric layer 194a, the first conductive layer 193a, the second conductive layer 192a, and the capping layer 191a may be sequentially disposed on the upper surface of the semiconductor substrate W. The gate dielectric layer 194a, the first conductive layer 193a, the second conductive layer 192a, and the capping layer 191a may each be formed parallel to the upper surface of the semiconductor substrate W.

Referring to FIG. 2F, a gate structure 290a may include a fin field effect transistor. The fin field effect transistor may include a gate dielectric layer 294a, a first conductive layer 293a, a second conductive layer 292a, a capping layer 291a, and a core gate structure channel CHL_F. The gate dielectric layer 294a, the first conductive layer 293a, the second conductive layer 292a, and the capping layer 291a may be sequentially disposed on the upper surface of the semiconductor substrate W. The gate dielectric layer 294a, the first conductive layer 293a, the second conductive layer 292a, and the capping layer 291a may each be formed parallel to the upper surface of the semiconductor substrate W. The core gate structure channel CHL_F may be disposed through the second conductive layer 292a, from a space between a plurality of source/drain regions SD to a central region of the second conductive layer 292a in the vertical direction. The core gate structure channel CHL_F may be electrically connected to the plurality of source/drain regions SD.

Referring to FIG. 2G, a gate structure 390a may include a recessed channel array transistor. The recessed channel array transistor may include a gate dielectric layer 394a, a first conductive layer 393a, a second conductive layer 392a, and a capping layer 391a. The gate dielectric layer 394a and the first conductive layer 393a may be recessed to the inside of the semiconductor substrate W. The recessed regions of the gate dielectric layer 394a and the first conductive layer 393a may be disposed in a space between a plurality of source/drain regions SD.

Referring to FIG. 2H, a gate line 490a may include a multi bridge channel field effect transistor. A multi bridge channel field effect transistor may include a plurality of nanosheet stacks NSS. The plurality of nanosheet stacks NSS may include a plurality of nanosheets N1, N2, and N3 that overlap each other in the vertical direction Z on an active region (not shown). The plurality of nanosheets N1, N2, and N3 may have different vertical distances (Z-direction distances) from the active region (not shown). The plurality of nanosheets N1, N2, and N3 may be referred to as a first nanosheet N1, a second nanosheet N2, and a third nanosheet N3, respectively, which may be sequentially stacked on the active region (not shown).

FIG. 2H illustrates a case where the planar shape of the nanosheet stacks NSS is approximately square, but the disclosure is not limited thereto. The nanosheet stacks NSS may have various planar shapes depending on the planar shape of each of the active region (not shown) and the gate line 490a. FIG. 2H illustrates an example configuration in which a plurality of nanosheet stacks NSS and a plurality of gate lines 490a may be disposed on an active region (not shown), and the plurality of nanosheet stacks NSS may be arranged in a row in a first horizontal direction X on the one active region (not shown). However, the number of each of the nanosheet stacks NSS and gate lines 490a disposed on the one active region (not shown) are not particularly limited.

Each of the plurality of gate lines 490a may include a main gate portion 493a and a plurality of sub-gate portions 492a. The main gate portion 493a may cover the upper surface of the nanosheet stack NSS and extend in a second direction Y. The plurality of sub-gate portions 492a may be integrally connected to the main gate portion 493a and arranged one by one between the plurality of nanosheets N1, N2, and N3 and between the active region (not shown) and the first nanosheet N1. In a vertical direction (Z direction), the thickness of each of the plurality of sub-gate portions 492a may be less than the thickness of the main gate portion 493a. The plurality of nanosheets N1, N2, and N3 may be surrounded by the gate line 490a.

The gate line 490a may include metal, metal nitride, or metal carbide, or a combination thereof. The metal may be, for example, Ti, W, Ru, Nb, Mo, Hf, Ni, Co, Pt, Yb, Tb, Dy, Er, or Pd. The metal nitride may be, for example, TiN or TaN. The metal carbide may include TiAlC.

A gate dielectric film may be located between the nanosheet stack NSS and the gate line 490a. In some embodiments, the gate dielectric film may have a stack structure of an interface film and a high-k dielectric film. The interface film may include a low-k dielectric material film having permittivity of about 9 or less, for example, a silicon oxide film or a silicon oxynitride film, or a combination thereof. In some embodiments, the interface film may be omitted. The high-k dielectric film may include a material having a higher dielectric constant than the silicon oxide film. For example, the high-k dielectric film may have a dielectric constant of about 10 to about 25. The high-k dielectric film may include hafnium oxide, but the disclosure is not limited thereto.

A plurality of inner insulating spacers 495a may be disposed between the plurality of nanosheets N1, N2, and N3 and between the active region (not shown) and the first nanosheet N1. Sidewalls of each of the plurality of sub-gate portions 492a may be covered by the inner insulating spacers 495a with the gate dielectric films therebetween. At least a portion of the plurality of inner insulating spacers 495a may overlap an outer insulating spacer 496a in the vertical direction Z.

Each of the inner insulating spacers 495a may include silicon nitride (SiN), SiCN, SiBN, SiON, SiOCN, SiBCN, SiOC, or silicon oxide (SiO), or a combination thereof. The inner insulating spacer 495a may further include an air gap. In some embodiments, the outer insulating spacer 496a and the inner insulating spacer 495a may include the same material. In some embodiments, the outer insulating spacer 496a and the inner insulating spacer 495a may include different materials.

The upper surface of the gate line 490a may be covered by a capping insulating pattern 491a. The capping insulating pattern 491a may include, for example, a silicon nitride film.

Each of a plurality of outer insulating spacers 496a may include silicon nitride (SiN), SiCN, SiBN, SiON, SiOCN, SiBCN, SiOC, or silicon oxide (SiO), or a combination thereof. Each of the terms “SiN”, “SiCN”, “SiBN”, “SiON”, “SiOCN”, “SiBCN”, “SiOC”, and “SiO” used herein indicates a material including elements shown in each term and may not be a chemical equation representing stoichiometric relationships.

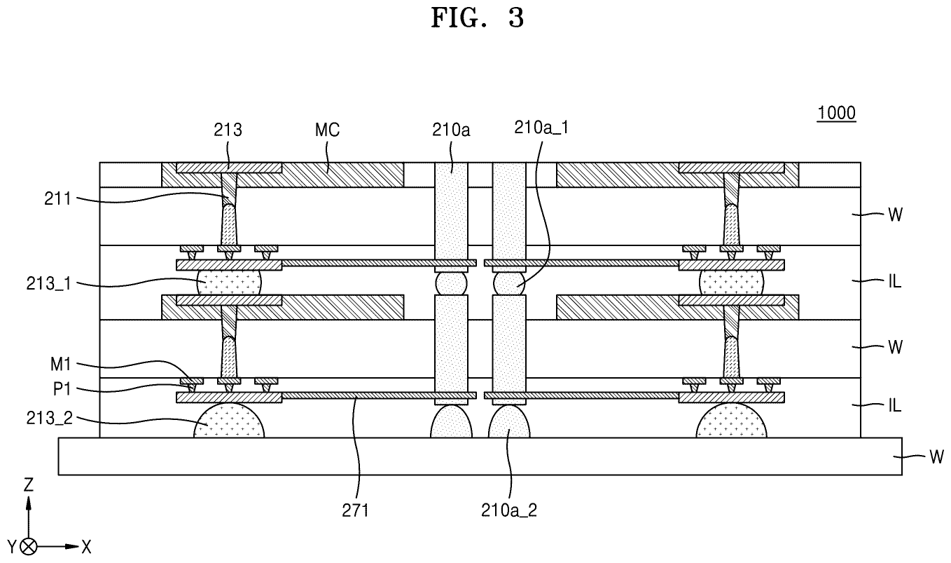

FIG. 3 is a cross-sectional view of a semiconductor package 1000 according to an embodiment.

The semiconductor package 1000 according to the inventive concept may include a plurality of integrated circuit devices stacked in a vertical direction Z and a plurality of connection terminals disposed between the integrated circuit devices and electrically connecting the integrated circuit devices to each other. The integrated circuit device described with reference to FIG. 3 may correspond to the integrated circuit device 10 described with reference to FIG. 1 and FIG. 2A.

Each of the plurality of integrated circuit devices may include a memory cell MC, an upper wiring pad 213, a power input unit 211, and a plurality of wiring layers M1 and a plurality of conductive plugs P1 electrically connected to the power input unit 211. The upper wiring pad 213 may be disposed in a portion of the memory cell MC. The power input unit 211 may pass through the semiconductor substrate W and may be electrically connect memory cells MC to each other. In addition, the plurality of integrated circuit devices may include a plurality of data output through-electrodes 210a and a plurality of floating pads 271 electrically connecting the memory cell MC to the plurality of data output through-electrodes 210a.

The plurality of connection terminals may include a cell connection terminal 213_1 electrically connecting a cell region including the plurality of memory cells MC to a peripheral circuit region and a plurality of data connection terminals 210a_1 electrically connecting the plurality of data output through-electrodes 210a to each other. In the semiconductor package 1000 shown in FIG. 3, components are arranged left and right symmetrically with respect to the central portion of the semiconductor substrate W, and the components may be formed in three layers in two rows. However, the numbers of rows and layers of the components are not limited to those shown in the drawings.

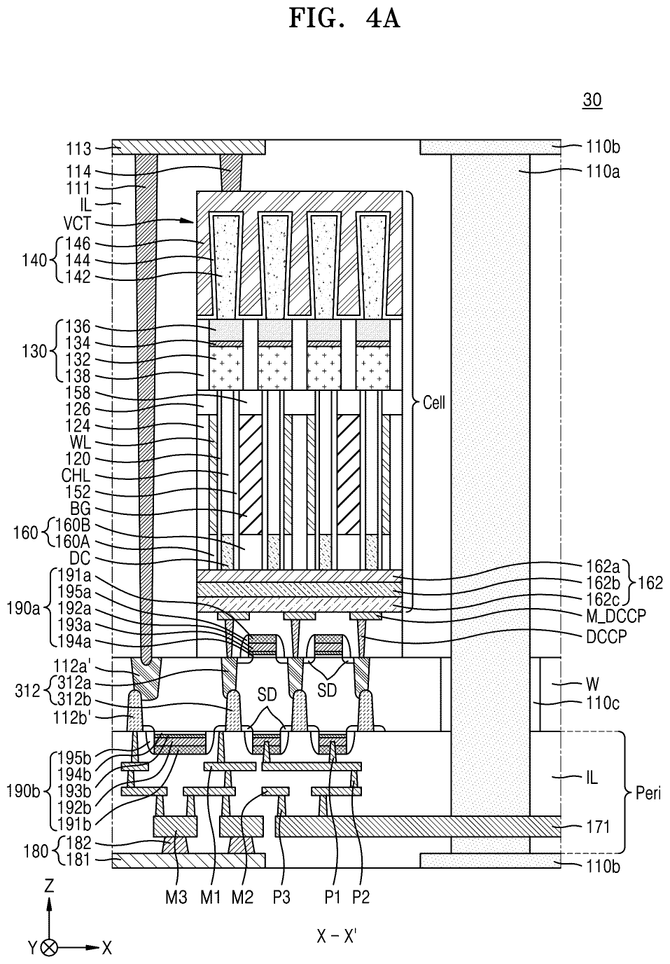

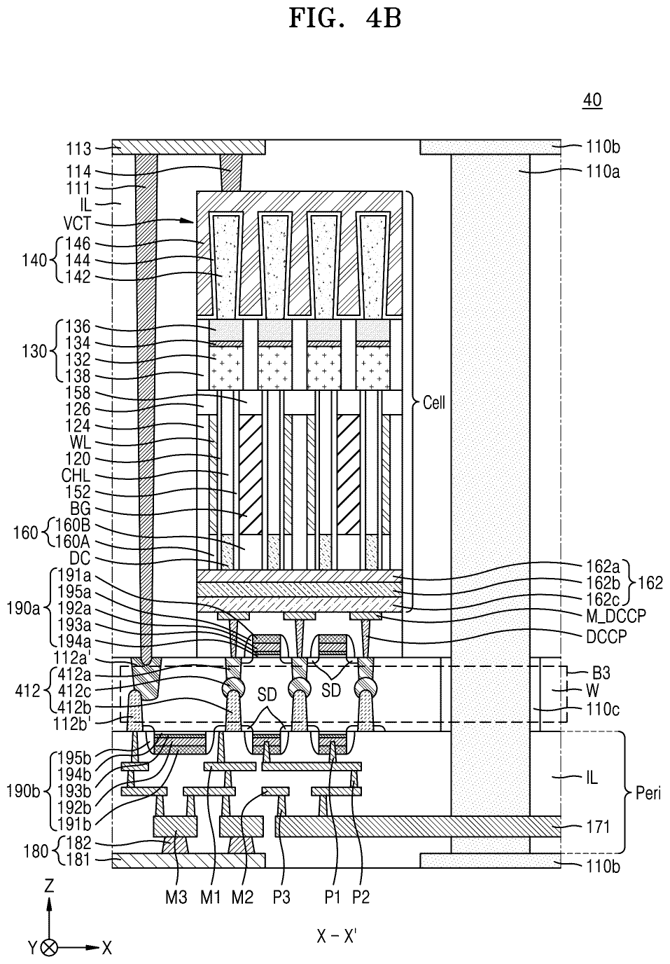

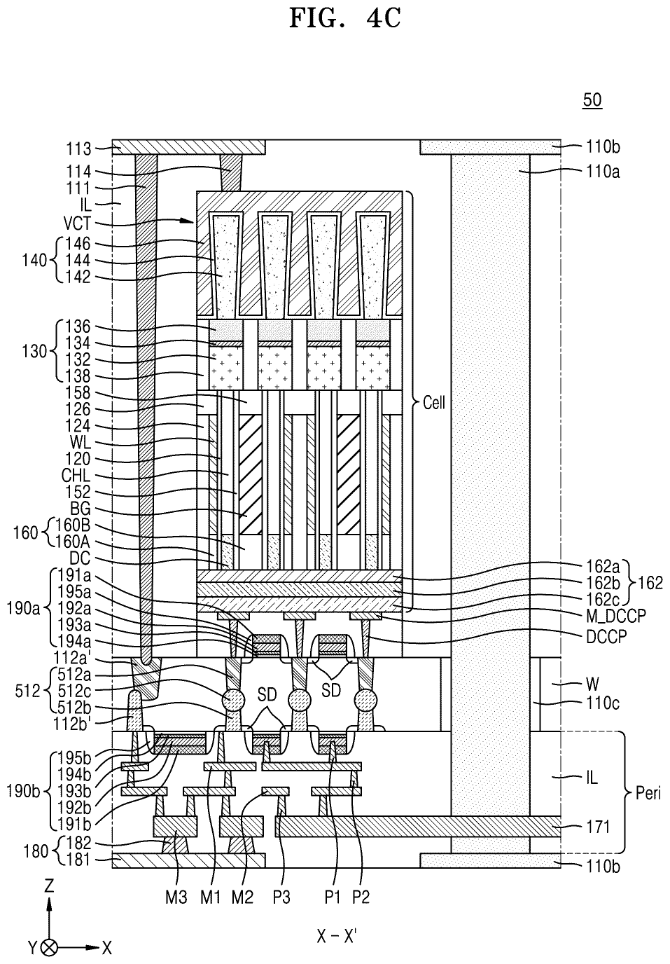

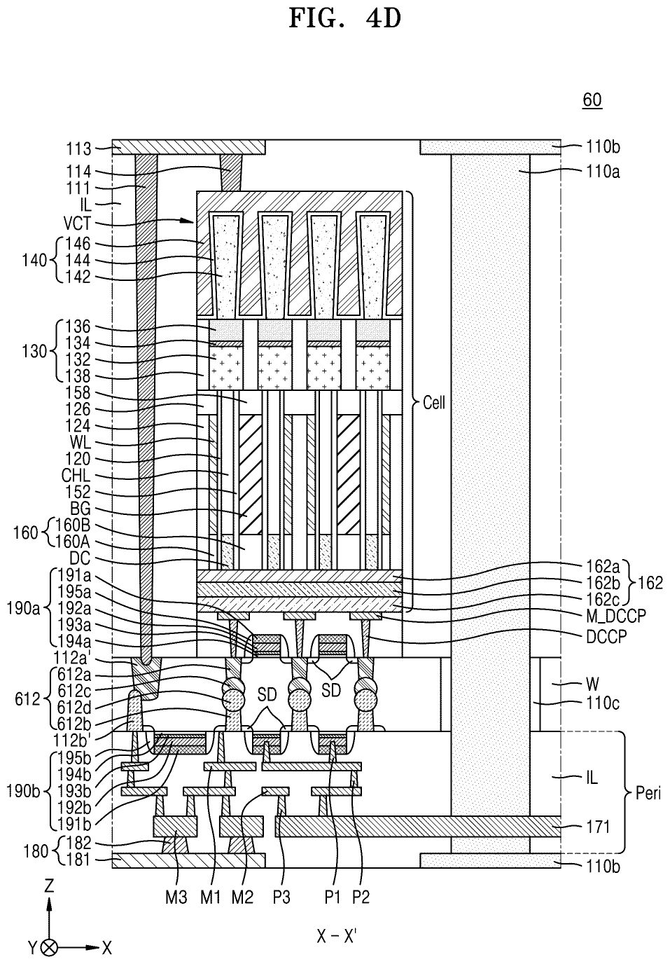

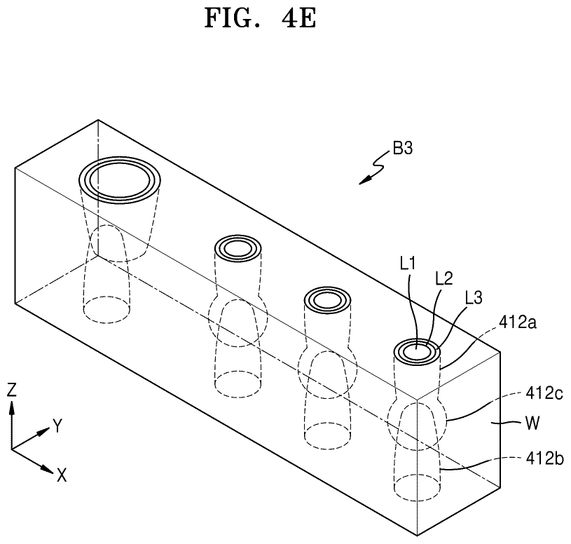

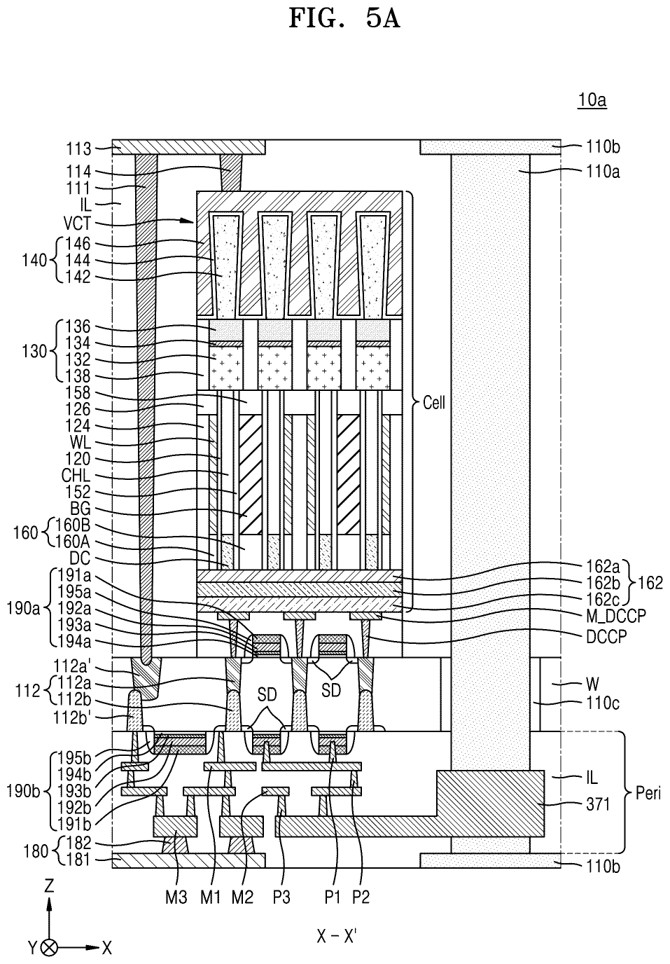

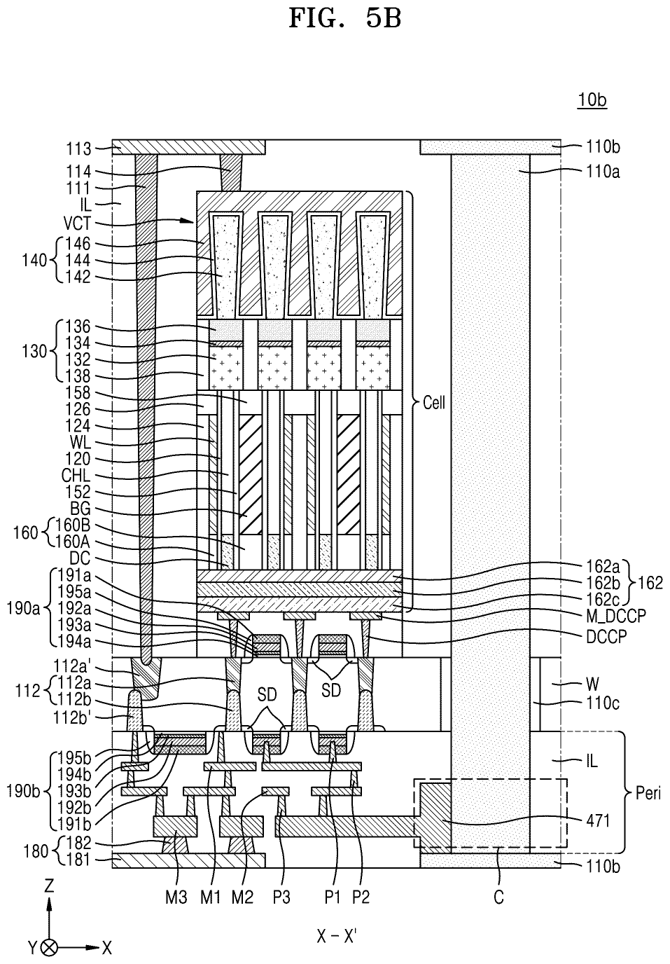

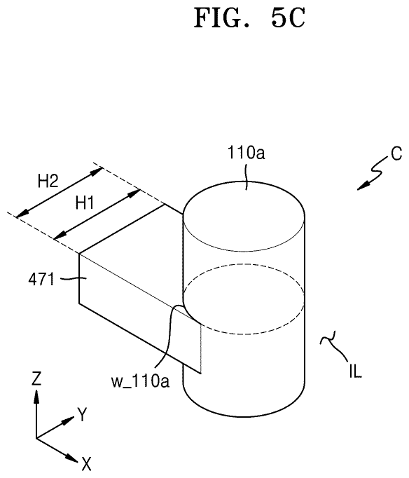

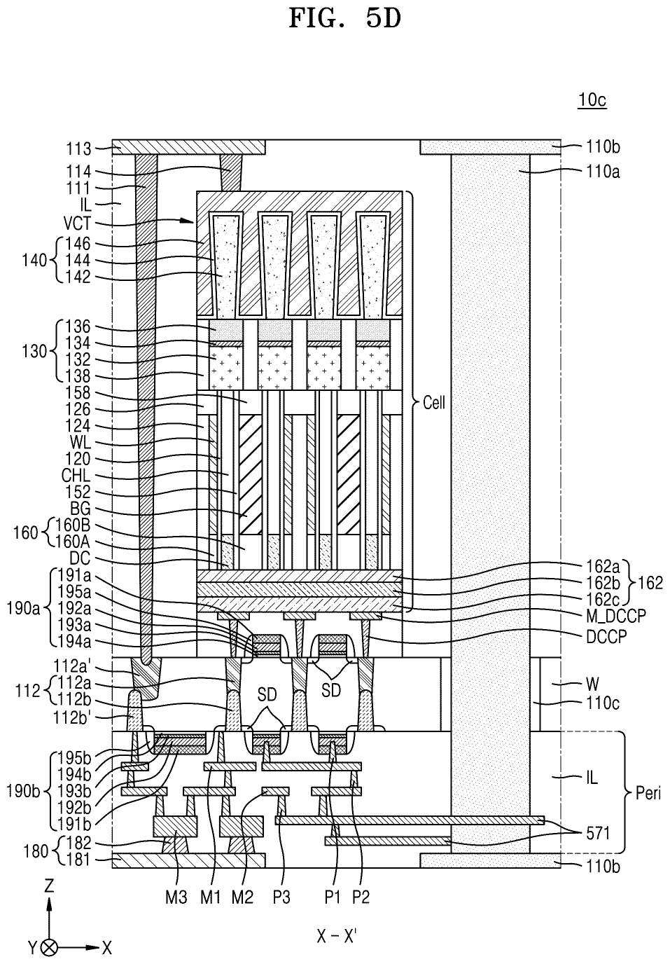

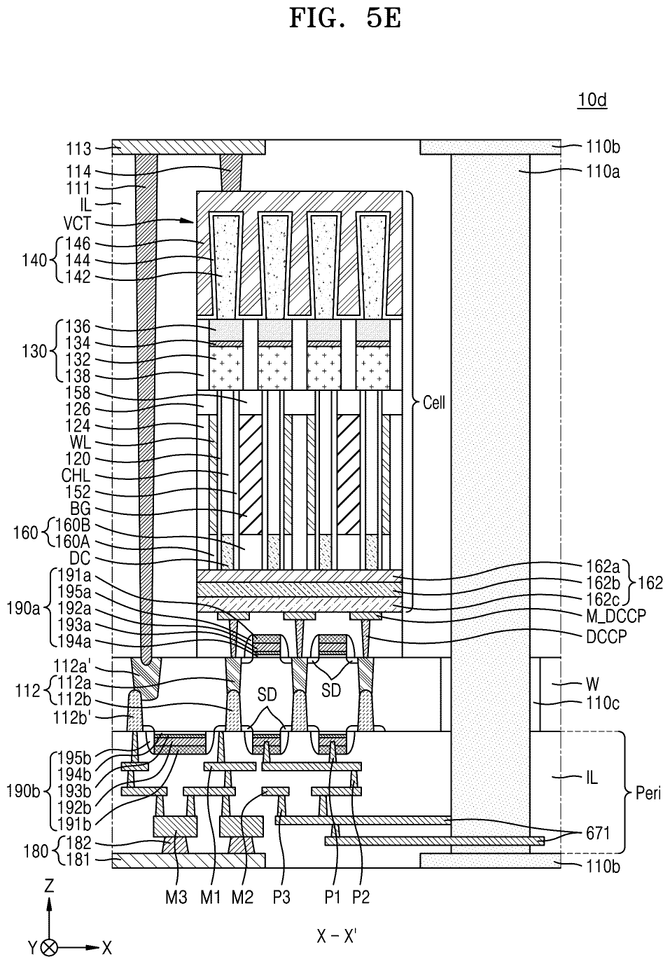

FIGS. 4A to 4D, and FIGS. 5A and 5B are cross-sectional views of integrated circuit devices according to some embodiments.

Referring to FIG. 4A, an integrated circuit device 30 according to an embodiment may include a plurality of bidirectional through-electrodes 312. The plurality of bidirectional through-electrodes 312 may include first small through-electrodes 312a and second small through-electrodes 312b. At least one of the plurality of bidirectional through-electrodes 312 may be disposed such that the axes of the first small through-electrodes 312a and the second small through-electrodes 312b in a vertical direction Z may be misaligned with each other.

Referring to FIG. 4B, an integrated circuit device 40 according to an embodiment may include a plurality of bidirectional through-electrodes 412. The plurality of bidirectional through-electrodes 412 may include a first small through-electrode 412a and a second small through-electrode 412b, and may further include a third small through-electrode 412c disposed between the first small through-electrode 412a and the second small through-electrode 412b. The third small through-electrode 412c may include the same material as either the first small through-electrode 412a or the second small through-electrode 412b. In order to form the integrated circuit device 40 of FIG. 4B, a first hole for the first small through-electrode 412a may be formed, and then an opening for the third small through-electrode 412c may be formed. Subsequently, the first hole and the opening may be filled with a material forming the first small through-electrode 412a. Then, a second hole for the second small through-electrode 412b may be formed, and the second hole may be filled with a material forming the second small through-electrode 412b. Accordingly, the third small through-electrode 412c may include the same material as the first small through-electrode 412a.

Referring to FIG. 4C, an integrated circuit device 50 according to an embodiment may include a plurality of bidirectional through-electrodes 512. The plurality of bidirectional through-electrodes 512 may include a first small through-electrode 512a and a second small through-electrode 512b, and may further include a third small through-electrode 512c disposed between the first small through-electrode 512a and the second small through-electrode 512b. The third small through-electrode 512c may include the same material as either the first small through-electrode 512a or the second small through-electrode 512b. In the case of FIG. 4C, first holes for the first small through-electrodes 512a may be formed, and then the plurality of first holes may be filled with a material forming the plurality of first small through-electrodes 512a. Subsequently, second holes for the second small through-electrodes 512b may be formed, and then openings for the third small through-electrodes 512c may be formed. The second holes and the openings may be filled with a material forming the second small through-electrodes 512b and the third small through-electrode 512c. Accordingly, the third small through-electrode 512c may include the same material as the second small through-electrode 512b.

Referring to FIG. 4D, an integrated circuit device 60 according to an embodiment may include a plurality of bidirectional through-electrodes 612. The plurality of bidirectional through-electrodes 612 may include a first small through-electrode electrode 612a, a second small through-electrode 612b, a third small through-electrode 612c disposed between the first small through-electrode electrode 612a and the second small through-electrode 612b, and a fourth small through-electrode 612d disposed between the third small through-electrode 612c and the second small through-electrode 612b. The third small through-electrode 612c and the fourth small through-electrode 612d may include the same material as either the first small through-electrode electrode 612a or the second small through-electrode 612b. In the case of FIG. 4D, the third small through-electrode 612c may include the same material as the first small through-electrode electrode 612a, and the fourth small through-electrode 612d may include the same material as the second small through-electrode 612b. Referring to FIG. 4B and FIG. 4C, the third small through-electrode or the fourth small through-electrode may have circular outer shapes, but the shapes thereof are not limited by the drawings.

FIG. 4E is an enlarged three-dimensional perspective view of region B3 of FIG. 4B. The repeated descriptions as those given with reference to FIG. 4B may be omitted.

Each of the first small through-electrode 412a and the second small through-electrode 412b may have a tapered shape of which a horizontal width may be reduced toward the center portion of a semiconductor substrate W in a vertical direction. The third small through-electrode 412c may have a spherical shape. A first hole for the first small through-electrode 412a may be formed, and then an opening for the third small through-electrode 412c may be formed. Subsequently, a second hole for the second small through-electrode 412b may be formed. When only the first small through-electrode 412a and the second small through-electrode 412b are formed, the contact area of the first small through-electrode 412a and the second small through-electrode 412b electrically connected to each other may correspond to the area of the end portion of the tapered shape. As the third small through-electrode 412c is disposed between the first small through-electrode 412a and the second small through-electrode 412b, the contact area between the first small through-electrode 412a and the second small through-electrode 412b may be further increased.

A plurality of layers may be deposited in the first hole, the second hole, and the opening for the first small through-electrode 412a, the second small through-electrode 412b, and the third small through-electrode 412c. The descriptions of the plurality of layers correspond to those given with reference to FIG. 2D and repetitive descriptions may be omitted.

Referring to FIG. 5A, an integrated circuit device 10a may include a floating pad 371. is the floating pad 371 may be electrically connected to a data output through-electrode 110a. The thickness of the floating pad 371 in a vertical direction Z may not be constant. The thickness of the floating pad 371 in the vertical direction Z in a region relatively close to the data output through-electrode 110a may be greater than the thickness of the floating pad 371 in the vertical direction Z in a region relatively far from the data output through-electrode 110a. The floating pad 371 in FIG. 5A may have a shape with a through-hole for accommodating the data output through-electrode 110a, and the data output through-electrode 110a may pass through the floating pad 371 in the vertical direction Z. The through-hole in FIG. 5A may correspond to the through-hole s_110a shown in FIG. 2B.

FIG. 5C is an enlarged three-dimensional perspective view of region C of FIG. 5B.

Referring to FIG. 5C together with FIG. 5B, an integrated circuit device 10b may include a floating pad 471. is the floating pad 471 may be electrically connected to a data output through-electrode 110a. The thickness of the floating pad 471 in a vertical direction Z may not be constant. The thickness of the floating pad 471 in the vertical direction Z in a region relatively close to the data output through-electrode 110a may be greater than the thickness of the floating pad 471 in the vertical direction Z in a region relatively far from the data output through-electrode 110a. The floating pad 471 may have a shape configured such that the floating pad 471 includes a sidewall w_110a in contact with the data output through-electrode 110a. When the floating pad 471 has a shape with the sidewall w_110a, a width H1 of the data output through-electrode 110a in the second direction Y may be equal to a width H2 of the floating pad 471 in the second direction Y.

Referring to FIG. 5D, an integrated circuit device 10c may include a pair of floating pads 571. The pair of floating pads 571 may be electrically connected to a data output through-electrode 110a. For the floating pads 571, a first floating pad of the pair of floating pads 571 may have a shape with a through-hole for accommodating the data output through-electrode 110a, and the data output through-electrode 110a may pass therethrough in the vertical direction Z. Also, a second floating pad of the pair of floating pads 571 may have a shape with a sidewall in contact with the data output through-electrode 110a. In FIG. 5D, the floating pads 571 may have two regions in direct physical contact with the data output through-electrode 110a. The floating pad 571 at an upper level may have a shape with the through-hole for accommodating the data output through-electrode 110a, and the data output through-electrode 110a may pass through the floating pad 571 in the vertical direction Z. For the floating pad 571 at a lower level among the pair of floating pads 571, the floating pad 571 may have a shape with the sidewall in contact with the data output through-electrode 110a. The through-hole of FIG. 5D may correspond to the through-hole s_110a of FIG. 2B and the sidewall of FIG. 5D may correspond to the sidewall w_110a of FIG. 5C.

Referring to FIG. 5E, an integrated circuit device 10d may include a pair of floating pads 671. The pair of floating pads 671 may be electrically connected to a data output through-electrode 110a. For the floating pads 671, a first floating pad of the pair of floating pads 671 may have a shape with a through-hole for accommodating the data output through-electrode 110a, and the data output through-electrode 110a may pass therethrough in the vertical direction Z. Also, a second floating pad of the pair of floating pads 671 may have a shape with a sidewall in contact with the data output through-electrode 110a. In FIG. 5E, the floating pads 671 have two regions in direct physical contact with the data output through-electrode 110a. For the floating pad 671 at an upper level among the pair of floating pads 671, the floating pad 671 may have a shape with the sidewall in contact with the data output through-electrode 110a.

The floating pad 671 at a lower level among the pair of floating pads 671 may have a shape with the through-hole for accommodating the data output through-electrode 110a, and the data output through-electrode 110a may pass through the floating pad 671 in the vertical direction Z. The through-hole of FIG. 5E may correspond to the through-hole s_110a of FIG. 2B and the sidewall of FIG. 5E may correspond to the sidewall w_110a of FIG. 5C.

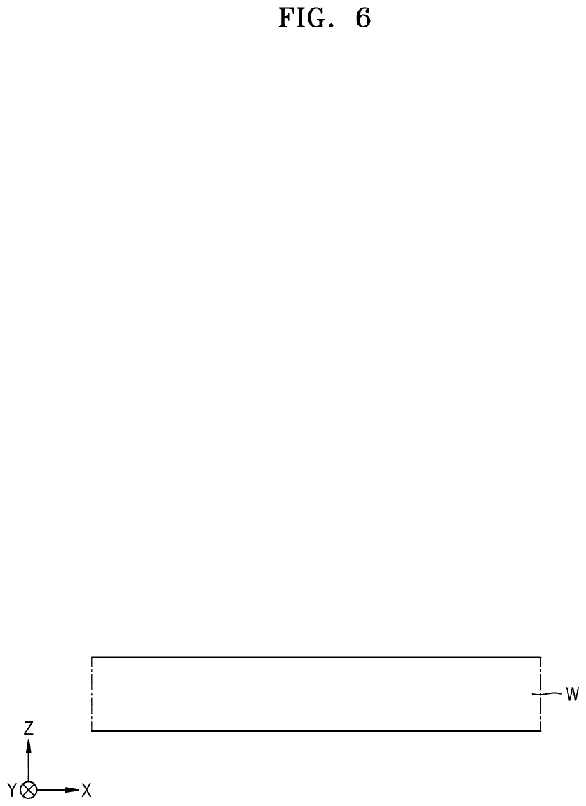

FIGS. 6 to 11 are cross-sectional views illustrating a method of manufacturing an integrated circuit device, according to an embodiment.

Referring to FIG. 6, a semiconductor substrate W may be provided, which has an upper surface and a lower surface opposite to the upper surface. The semiconductor substrate W may extend in a first direction and a second direction perpendicular to the first direction.

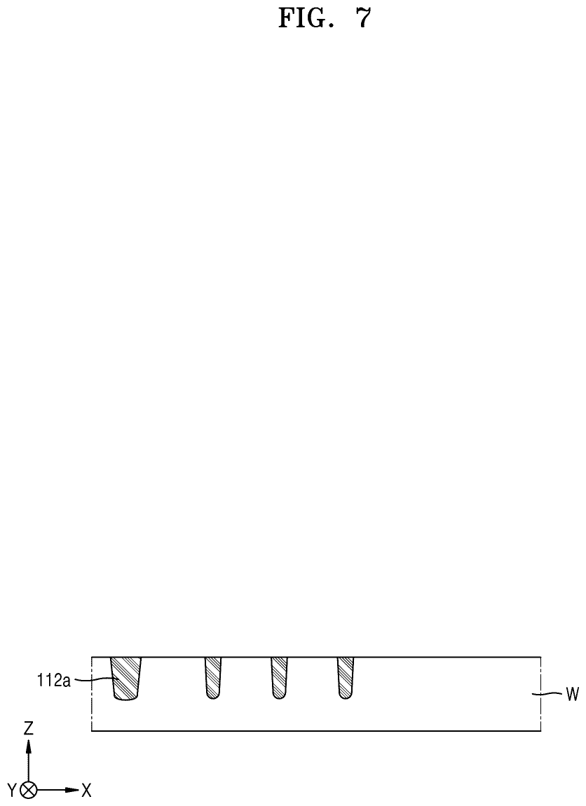

Referring to FIG. 7, a plurality of first small through-electrodes 112a may be formed, passing through a portion of the semiconductor substrate W from the upper surface of the semiconductor substrate W in a vertical direction Z.

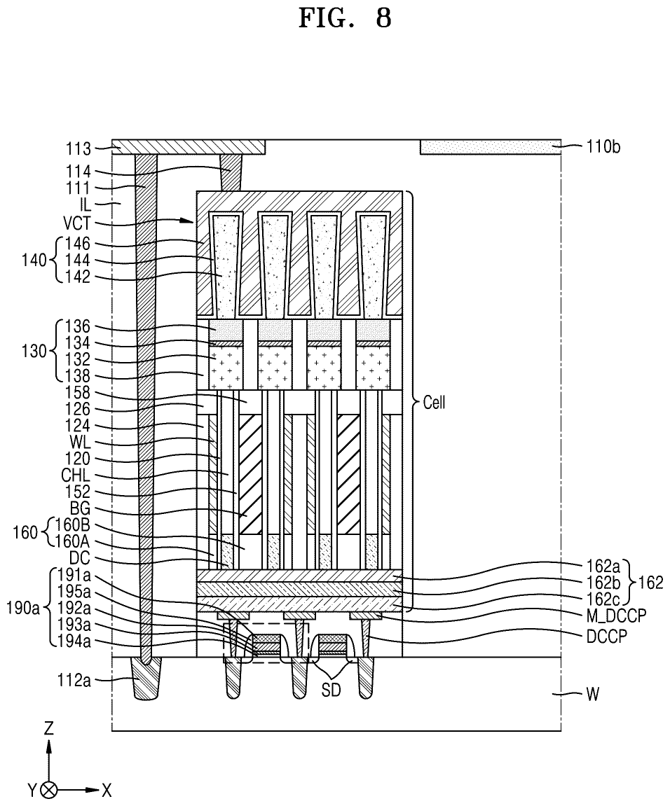

Referring to FIG. 8, a power input unit 111 may be formed. The power input unit 111 may be connected to at least one of the plurality of first small through-electrodes 112a. A cell region Cell may be provided and electrically connected to at least one of the plurality of first small through-electrodes 112a. The cell region Cell may be electrically connected to the plurality of first small through-electrodes 112a via a plurality of direct contact plug wiring layers M_DCCP and a plurality of direct contact plugs DCCP respectively connected to the plurality of direct contact plug wiring layers M_DCCP, which may be disposed below the cell region Cell. A plurality of core gate structures 190a may be arranged between the plurality of direct contact plugs DCCP. A cell connector 114 may be provided, and may be electrically connected to the cell region Cell. An upper wiring pad 113 may be provided, and may electrically connect the cell connector 114 to the power input unit 111. A data output pad 110b may be formed on a side of the upper wiring pad 113.

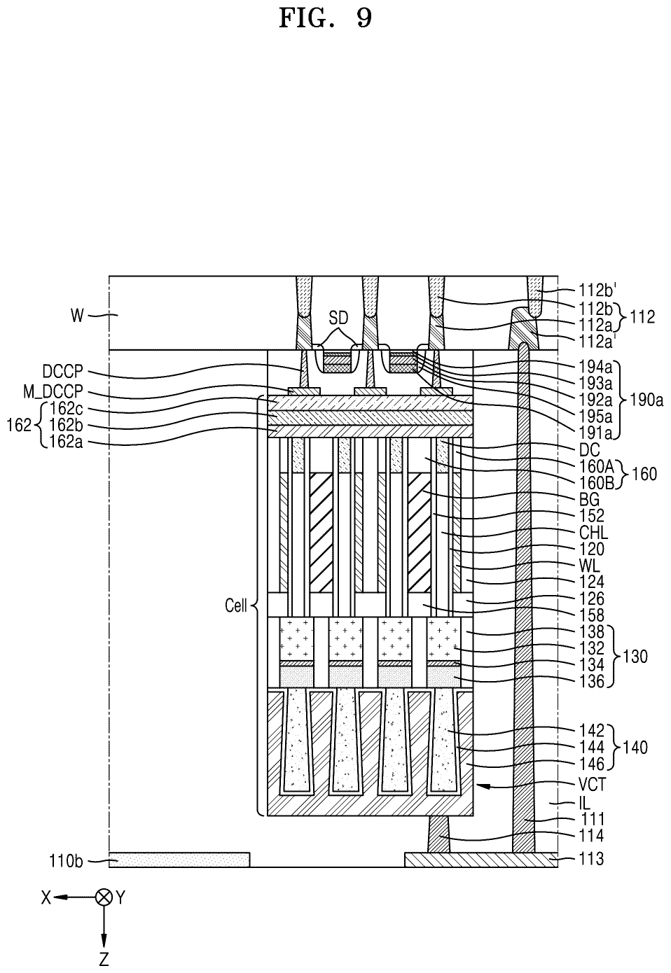

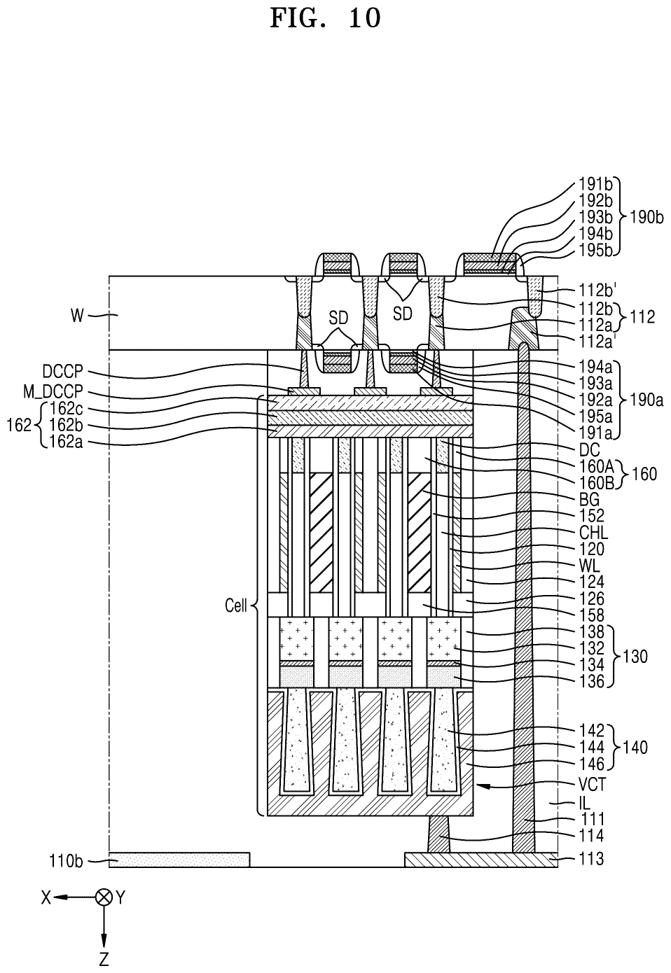

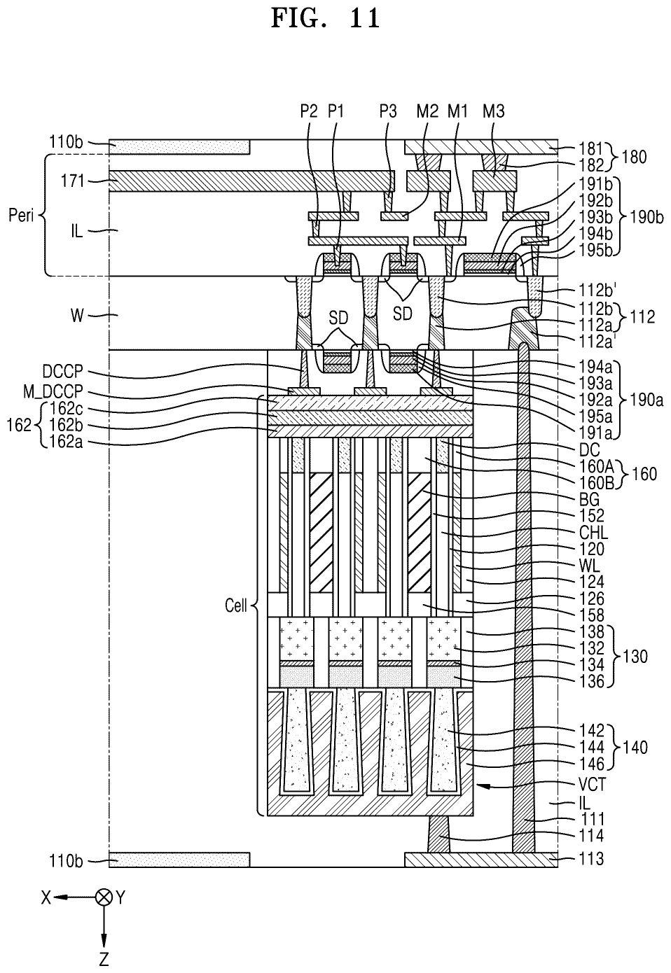

Referring to FIG. 9, FIG. 10 and FIG. 11, a plurality of second small through-electrodes 112b, including a peripheral second small through-electrode 112b′, may be formed, passing through another portion of the semiconductor substrate W from the lower surface of the semiconductor substrate W in the vertical direction Z. For example, the components arranged in FIG. 8 may be rotated by 180 degrees about a second direction Y and the plurality of second small through-electrodes 112b may be formed.

Referring to FIG. 10 and FIG. 11, a plurality of peripheral gate structures 190b electrically connected to the plurality of second small through-electrodes 112b may be disposed on the lower surface of the semiconductor substrate W. Subsequently, the plurality of peripheral gate structures 190b and a peripheral circuit region Peri may be formed. A plurality of source/drain regions SD may be formed on sides of each of a plurality of second small through-electrodes 112b and the peripheral second small through-electrode 112b′. Some regions of the plurality of source/drain regions SD on sides of each of the plurality of second small through-electrodes 112b and the peripheral second small through-electrode 112b′ may be electrically connected to the plurality of peripheral gate structures 190b.

More specifically, there may be formed: a plurality of wiring layers M1, M2, and M3 electrically connected to each other; a plurality of conductive plugs P1, P2, and P3 each in contact with and connected to some of the plurality of wiring layers M1, M2, and M3; and an insulating layer IL surrounding the plurality of wiring layers M1, M2, and M3 and the plurality of conductive plugs P1, P2, and P3. Also, a data output pad 110b and a lower wire 180 including a lower wiring pad 181 and a lower wiring plug 182 may be formed on a side of the peripheral circuit region Peri.

Referring to FIG. 11 together with FIG. 2A, at least one data output through-electrode 110a may be formed, which may pass through the semiconductor substrate W and may be connected to two data output pads 110b selected from among the plurality of data output pads 110b. As a result, the integrated circuit device 10 of FIG. 2A may be formed. In order to form the data output through-electrode 110a, an atomic layer deposition (ALD) process or a chemical vapor deposition (CVD) process may be used.

The method of manufacturing the integrated circuit device 10 illustrated in FIG. 2A has been described with reference to FIGS. 6 to 11. However, based on the descriptions given with reference to FIGS. 6 to 11, it is understood by those skilled in the art that the integrated circuit devices 30, 40, 50, 60, 10a, 10b, 10c, and 10d illustrated in FIGS. 4A to 4E and FIG. 5A to 5E and other integrated circuit devices having various structures modified and changed therefrom can be manufactured by making various modifications and changes within the scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a semiconductor substrate having an upper surface and a lower surface opposite to the upper surface;
a plurality of data output pads spaced apart from the semiconductor substrate in a vertical direction;
a data output through-electrode passing through the semiconductor substrate in the vertical direction and connected to the plurality of data output pads;
a plurality of bidirectional through-electrodes comprising a plurality of first small through-electrodes each passing through a first portion of the semiconductor substrate from the upper surface of the semiconductor substrate in the vertical direction and a plurality of second small through-electrodes each passing through a second portion of the semiconductor substrate from the lower surface of the semiconductor substrate in the vertical direction;
a power input unit electrically connected to at least one of the plurality of first small through-electrodes;
a cell region located disposed between the power input unit and the data output through-electrode and electrically connected to at least one of the plurality of first small through-electrodes; and
a peripheral circuit region comprising a plurality of peripheral gate structures electrically connected to at least one of the plurality of second small through-electrodes.

2. The integrated circuit device of claim 1, wherein, when power is defined as a product of a magnitude of voltage and a magnitude of current,
the data output through-electrode is configured to receive first power,
the power input unit is configured to receive second power, and
the first power is less than the second power.

3. The integrated circuit device of claim 1, wherein the peripheral circuit region comprises a floating pad electrically connecting the plurality of peripheral gate structures to the data output through-electrode, wherein the floating pad is spaced apart, in the vertical direction, from a data output pad of the plurality of data output pads disposed below the lower surface of the semiconductor substrate.

4. The integrated circuit device of claim 3, wherein, in a plan view, the floating pad has a sidewall in contact with the data output through-electrode.

5. The integrated circuit device of claim 1, wherein each of the plurality of first small through-electrodes and the plurality of second small through-electrodes has a tapered shape of which a horizontal width is reduced toward a center portion of the semiconductor substrate in the vertical direction, and
the horizontal width of the plurality of first small through-electrodes and the horizontal width of the plurality of second small through-electrodes away from the center portion of the semiconductor substrate is less than a horizontal width of the data output through-electrode.

6. The integrated circuit device of claim 1, wherein a vertical length of at least one of the plurality of first small through-electrodes or the plurality of second small through-electrodes is less than half a vertical length of the semiconductor substrate.

7. The integrated circuit device of claim 1, wherein the plurality of first small through-electrodes and the plurality of second small through-electrodes are electrically and respectively connected to each other,
an end portion of each of the plurality of first small through-electrodes has a concave shape, and
an end portion of each of the plurality of second small through-electrodes has a convex shape disposed on the end portion of a respective one of the plurality of first small through-electrodes.

8. The integrated circuit device of claim 1, further comprising:
an upper wiring pad disposed on the power input unit and electrically connected to the power input unit; and
a cell connector disposed between the upper wiring pad and the cell region,
wherein the cell region comprises a plurality of capacitors, and
the cell connector electrically connects the upper wiring pad to the plurality of capacitors.

9. The integrated circuit device of claim 1, wherein the peripheral circuit region further comprises:
a plurality of wiring layers electrically connected to the plurality of second small through-electrodes;
a plurality of conductive plugs in contact with some of the plurality of wiring layers; and
an insulating layer surrounding the plurality of wiring layers and the plurality of conductive plugs.

10. The integrated circuit device of claim 1, wherein the cell region is disposed on the upper surface of the semiconductor substrate,
the peripheral circuit region is disposed on the lower surface of the semiconductor substrate, and
the data output through-electrode connects a first data output pad of the plurality of data output pads disposed above the upper surface of the semiconductor substrate to a second data output pad of the plurality of data output pads disposed below the lower surface of the semiconductor substrate.

11. An integrated circuit device comprising:
a semiconductor substrate having an upper surface and a lower surface opposite to the upper surface, the semiconductor substrate extending in a first direction and a second direction perpendicular to the first direction;
a cell region disposed above the upper surface of the semiconductor substrate and comprising a vertical channel transistor and a plurality of capacitors electrically connected to the vertical channel transistor;
a power input unit disposed on a first side of the cell region and electrically connected to the cell region;
a plurality of data output pads spaced apart from the semiconductor substrate in a vertical direction;
a data output through-electrode disposed on a second side of the cell region opposite the power input unit in a horizontal direction, the data output through-electrode passing through the semiconductor substrate in the vertical direction and connected to the plurality of data output pads, and providing a path to output data from the cell region;
a peripheral circuit region disposed on the lower surface of the semiconductor substrate, the peripheral circuit region electrically connected to the power input unit and the data output through-electrode and comprising a plurality of peripheral gate structures; and
a plurality of bidirectional through-electrodes comprising a plurality of first small through-electrodes each electrically connected to the cell region and passing through a first portion of the semiconductor substrate from the upper surface of the semiconductor substrate in the vertical direction and a plurality of second small through-electrodes each electrically connected to the peripheral circuit region and passing through a second portion of the semiconductor substrate from the lower surface of the semiconductor substrate in the vertical direction,
wherein, when power is defined as a product of a magnitude of voltage and a magnitude of current,
the data output through-electrode is configured to receive first power,
the power input unit is configured to receive second power, and
the first power is less than the second power,
wherein the peripheral circuit region further comprises a floating pad electrically connecting the plurality of peripheral gate structures to the data output through-electrode, wherein the floating pad is spaced apart from a data output pad of the plurality of data output pads disposed below the lower surface of the semiconductor substrate.

12. The integrated circuit device of claim 11, wherein, in a plan view, the floating pad has a sidewall in contact with the data output through-electrode.

13. The integrated circuit device of claim 11, wherein, in a plan view, the floating pad includes a through-hole with a shape accommodating the data output through-electrode, and the data output through-electrode passes through the through-hole of the floating pad in the vertical direction.

14. The integrated circuit device of claim 13, wherein a width of the data output through-electrode in the second direction is less than a width of the floating pad in the second direction.

15. The integrated circuit device of claim 11, wherein the plurality of first small through-electrodes and the plurality of second small through-electrodes are electrically and respectively connected to each other,
an end portion of each of the plurality of first small through-electrodes has a concave shape, and
an end portion of each of the plurality of second small through-electrodes has a convex shape disposed on the end portion of a respective one of the plurality of first small through-electrodes,
wherein at least one of the plurality of bidirectional through-electrodes is configured such that axes of the plurality of first small through-electrodes and the plurality of second small through-electrodes are misaligned with each other.

16. The integrated circuit device of claim 11, wherein the plurality of bidirectional through-electrodes further comprise a plurality of third small through-electrodes disposed between the plurality of first small through-electrodes and the plurality of second small through-electrodes,
wherein each third small through-electrode of the plurality of third small through-electrodes comprises a same material as one of the plurality of first small through-electrodes or the plurality of second small through-electrodes.

17. The integrated circuit device of claim 11, wherein each of the plurality of first small through-electrodes and the plurality of second small through-electrodes has a tapered shape of which a horizontal width is reduced toward a center portion of the semiconductor substrate in the vertical direction, and
a maximum value of the horizontal widths of the plurality of first small through-electrodes and the plurality of second small through-electrodes is less than a horizontal width of the data output through-electrode.

18. The integrated circuit device of claim 11, wherein the vertical channel transistor comprises:
a conductive line extending in the first direction;
a plurality of channel regions disposed on the conductive line, spaced apart from each other in the first direction, and electrically connected to the conductive line;
a back gate electrode selected from among the plurality of channel regions, extending lengthwise in the second direction between a first channel region and a second channel region adjacent to each other, and spaced apart from the conductive line in the vertical direction; and
a pair of word lines selected from among the plurality of channel regions, arranged between the second channel region and a third channel region adjacent to each other, and spaced apart from each other in the first direction,
wherein the conductive line comprises a plurality of layers.

19. A semiconductor package comprising:
a plurality of integrated circuit devices stacked in a vertical direction; and
a plurality of connection terminals disposed between the plurality of integrated circuit devices and configured to electrically connect the plurality of integrated circuit devices to each other,
wherein each integrated circuit device of the plurality of integrated circuit devices comprises:
a semiconductor substrate having an upper surface and a lower surface opposite to the upper surface, the semiconductor substrate extending in a first direction and a second direction perpendicular to the first direction;
a cell region disposed above the upper surface of the semiconductor substrate and comprising a vertical channel transistor and a plurality of capacitors electrically connected to the vertical channel transistor;
a plurality of bidirectional through-electrodes comprising a plurality of first small through-electrodes each passing through a first portion of the semiconductor substrate from the upper surface of the semiconductor substrate in the vertical direction and a plurality of second small through-electrodes each passing through a second portion of the semiconductor substrate from the lower surface of the semiconductor substrate in the vertical direction;
a data output through-electrode passing through the semiconductor substrate in the vertical direction and electrically connected to a floating pad located in a peripheral circuit region and configured to output data;
a power input unit connected to at least one of the plurality of bidirectional through-electrodes and configured to input power; and
a cell connector disposed on a side of the power input unit and configured to electrically connect the power input unit and the cell region to each other,
wherein the plurality of first small through-electrodes and the plurality of second small through-electrodes are electrically and respectively connected to each other,
wherein, when power is defined as a product of a magnitude of voltage and a magnitude of current,
the data output through-electrode is configured to receive first power,
the power input unit is configured to receive second power, and
the first power is less than the second power,
wherein the floating pad is in direct physical contact with the data output through-electrode,
the cell region is disposed above the upper surface of the semiconductor substrate, and
the peripheral circuit region is disposed on the lower surface of the semiconductor substrate,
wherein the plurality of connection terminals comprise:
a cell connection terminal configured to electrically connect the plurality of cell regions and the peripheral circuit region to each other; and
a data connection terminal configured to electrically connect the plurality of data output through-electrodes to each other.

20. The semiconductor package of claim 19, wherein each of the plurality of first small through-electrodes and the plurality of second small through-electrodes has a tapered shape of which a horizontal width is reduced toward a center portion of the semiconductor substrate in the vertical direction, and
a maximum value of the horizontal widths of the plurality of first small through-electrodes and the plurality of second small through-electrodes is less than a horizontal width of the data output through-electrode,
wherein a vertical length of at least one of the plurality of first small through-electrodes or the plurality of second small through-electrodes is less than half a vertical length of the semiconductor substrate,
an end portion of each of the plurality of first small through-electrodes has a concave shape, and
an end portion of each of the plurality of second small through-electrodes has a convex shape disposed on the end portion of a respective one of the plurality of first small through-electrodes.
